(19) United States
(12) Patent Application Publication
(10) Pub. No.: US 2025/0178150 A1
(43) Pub. Date: Jun. 5, 2025

(54) SUBSTRATE POLISHING METHOD

(71) Applicant: EBARA CORPORATION, Tokyo (JP)

(72) Inventors: Satoru YAMAMOTO, Tokyo (JP); Keisuke UCHIYAMA, Tokyo (JP); Makoto KASHIWAGI, Tokyo (JP); Mao FUJISAWA, Tokyo (JP)

(21) Appl. No.: 18/842,680

(22) PCT Filed: Feb. 17, 2023
(86) PCT No.: PCT/JP2023/005648

§ 371 Date: Aug. 29, 2024

(30) Foreign Application Priority Data
Mar. 8, 2022 (JP) 2022-035065

(51) Int. Cl. B24B 21/06

(52) U.S. Cl. CPC B24B 21/06

(57) ABSTRACT

The present invention relates to a substrate polishing method of polishing a substrate, such as a wafer. The substrate polishing method includes: rotating a substrate (W) about its own axis, while causing the substrate (W) and a polishing head (10C) to make a circular motion relative to each other; and pressing a polishing tape (2B) against a surface (5a) of the substrate (W) by the polishing head (10C) while feeding the polishing tape (2B) in a longitudinal direction thereof to thereby polish a central region including a center (O1) of the substrate (W) and an outer region adjacent to the central region. A process of polishing the central region and the outer region includes at least two polishing processes performed under different polishing conditions. The at least two polishing processes include: a low polishing-rate process performed under a polishing condition such that a polishing rate in the central region is lower than a polishing rate in the outer region; and a high polishing-rate process performed under a polishing condition such that a polishing rate in the central region is higher than a polishing rate in the outer region.

### TECHNICAL FIELD

The present invention relates to a substrate polishing method of polishing a substrate, such as a wafer.

### BACKGROUND ART

Devices, such as memory circuits, logic circuits, and image sensors (e.g., CMOS sensors), are becoming more highly integrated these days. In a process of forming such devices, foreign matter, such as fine particles or dust, may adhere to the devices. Foreign matter adhering to a device can cause a short-circuit between interconnects or can cause a circuit defect. Therefore, in order to enhance a reliability of the device, it is necessary to clean a substrate on which the device is formed to remove the foreign matter on the substrate.

Foreign matter, such as fine particles or dust, as described above, or an excessive film unintentionally formed in a film forming process may also adhere to a back surface (or a non-device surface) of the substrate. If such foreign matter or an excessive film adheres to the back surface of the substrate, the substrate can separate from a stage reference plane of an exposure apparatus, so that a surface of the substrate can incline with respect to the stage reference plane. As a result, patterning shift or focal distance shift can occur. In order to prevent such problems, it is necessary to remove the foreign matter or the excessive film adhering to the back surface of the substrate.

Thus, a substrate polishing apparatus for polishing the back surface of the substrate by pressing a polishing tape against the back surface of the substrate with a polishing head is used. Demand for an apparatus that can polish the entire surface of the substrate more efficiently has recently increased. Therefore, there has been proposed a substrate polishing apparatus that polishes the back surface of the substrate while causing the polishing head and the substrate to make a circular motion relative to each other to be able to ensure a relative speed between a pressing member of the polishing head and the substrate.

FIG. 18 is a plan view of a conventional substrate polishing apparatus configured to polish a back surface of a substrate W with a polishing tape 502 while causing the substrate W to make a circular motion, and FIG. 19 is a side view of the conventional substrate polishing apparatus shown in FIG. 18. A substrate holder 510 of the substrate polishing apparatus has a plurality of rollers 500, and a plurality of eccentric shafts 507 fixed to the plurality of rollers 500, respectively.

As shown in FIG. 19, each eccentric shaft 507 has a first shaft portion 507a, and a second shaft portion 507b decentered by a distance “e” from the axis of the first shaft portion 507a. Each of the rollers 500 is fixed to one end of the second shaft portion 507b. Each of the first shaft portions 507a is coupled to a motor 509. When the motor 509 is in motion, the roller 500 makes a circular motion with a radius “e” about the axis of the second shaft portion 507b, and the roller 500 itself rotates about its own axis. Therefore, the substrate holder 510 rotates the substrate W about its own axis O1 while causing the substrate W to make a circular motion with the radius “e”.

The polishing tape 502 is arranged at a back-surface side of the substrate W. A predetermined tension is applied to the polishing tape 502 while the polishing tape 502 advances in a direction indicated by arrow Z in FIGS. 18 and 19. A plurality of pressing members 505A to 505D are aligned in a radial direction of the substrate W. The polishing tape 502 is pressed against the back surface of the substrate W with the pressing members 505A to 505D, so that the back surface of the substrate W is polished. Such a conventional substrate polishing apparatus can cause the pressing members 505A to 505D and the substrate W to make a circular motion relative to each other and can therefore polish a central portion of the substrate W which could not be polished with a sufficient polishing force only by rotation of the substrate W. Therefore, the entire back surface of the substrate W can be efficiently polished.

### CITATION LIST

### Patent Literature

Patent document 1: Japanese laid-open patent publication No. 2019-77003

### SUMMARY OF INVENTION

### Technical Problem

However, when the back surface of the substrate W is polished while the pressing members 505A to 505D and the substrate W are moved in the circular motion relative to each other, a central region CR including the center O1 of the substrate W shown in FIG. 18 keeps being pressed by the pressing member 505C for a relatively longer time than that in other regions. Therefore, the central region CR of the substrate W may be excessively polished compared to a region other than the central region CR. As a result, the substrate polishing apparatus may not be able to uniformly polish the back surface of the substrate W.

Thus, the present invention provides a substrate polishing method capable of polishing an entire surface of a substrate at a uniform polishing rate.

### Solution to Problem

In an embodiment, there is provided a substrate polishing method of polishing a surface of a substrate, comprising: rotating the substrate about its own axis, while causing the substrate and a polishing head to make a circular motion relative to each other; and pressing a polishing tape against the surface of the substrate by the polishing head while feeding the polishing tape in a longitudinal direction thereof to thereby polish a central region including a center of the substrate and an outer region adjacent to the central region, wherein a process of polishing the central region and the outer region includes at least two polishing processes performed under different polishing conditions, and the at least two polishing processes include: a low polishing-rate process performed under a polishing condition such that a polishing rate in the central region is lower than a polishing rate in the outer region; and a high polishing-rate process performed under a polishing condition such that a polishing rate in the central region is higher than a polishing rate in the outer region.

In an embodiment, a parameter of the polishing condition includes at least one of a tape pressing force generated by the polishing head, a tape tension of the polishing tape, a position of a guide roller configured to guide the polishing tape, the guide roller being arranged adjacent to the polishing head, an outer diameter of the guide roller, a length of a pressing member of the polishing head, the pressing member being configured to press the polishing tape against the substrate, an angle of the pressing member inclined downwardly toward the center of the substrate, and a hardness of the pressing member.

In an embodiment, the tape pressing force in the polishing condition of the high polishing-rate process is larger than the tape pressing force in the polishing condition of the low polishing-rate process.

In an embodiment, the tape tension of the polishing tape in the polishing condition of the high polishing-rate process is smaller than the tape tension of the polishing tape in the polishing condition of the low polishing-rate process.

In an embodiment, the position of the guide roller in the polishing condition of the high polishing-rate process is higher than the position of the guide roller in the polishing condition of the low polishing-rate process.

In an embodiment, the angle of the pressing member inclined downwardly toward the center of the substrate in the polishing condition of the high polishing-rate process is smaller than the angle of the pressing member inclined downwardly toward the center of the substrate in the polishing condition of the low polishing-rate process.

### Advantageous Effects of Invention

The substrate polishing method includes at least two polishing processes including the low polishing-rate process such that the polishing rate in the central region of the substrate is low and the high polishing-rate process such that the polishing rate in the central region of the substrate is high. Therefore, the entire surface of the substrate can be polished at a uniform polishing rate without excessive polishing of the central region of the substrate.

### BRIEF DESCRIPTION OF DRAWINGS

FIG. 1 is a side view showing an embodiment of a substrate polishing apparatus;

FIG. 2 is a plan view of the substrate polishing apparatus shown in FIG. 1;

FIG. 3 is a schematic diagram showing an embodiment of a guide-roller position adjusting mechanism;

FIG. 4 is a perspective view showing an embodiment of a polishing head;

FIG. 5 is a plan view of the polishing head shown in FIG. 4;

FIG. 6 is a graph showing a relationship between a position from the center of a substrate and a polishing rate in a low polishing-rate process;

FIG. 7 is a graph showing a relationship between a position from the center of the substrate and a polishing rate in a high polishing-rate process;

FIG. 8 is a diagram illustrating a variation of polishing rate in a central region with a difference in tape pressing force;

FIG. 9 is a diagram illustrating a variation of polishing rate in the central region with a difference in tape tension;

FIG. 10 is a diagram illustrating a variation of polishing rate in the central region with a difference in position of a guide roller arranged adjacent to the polishing head;

FIG. 11 is a diagram illustrating a variation of polishing rate in the central region with a difference in angle of a pressing member of the polishing head;

FIG. 12 is a diagram illustrating a variation of polishing rate in the central region with a difference in outer diameter of the guide roller arranged adjacent to the polishing head;

FIG. 13 is a diagram illustrating a variation of polishing rate in the central region with a difference in length of the pressing member of the polishing head;

FIG. 14 is a graph showing a relationship between the position from the center of the substrate and a polishing rate in a polishing process including the low polishing-rate process and the high polishing-rate process;

FIG. 15 is a flowchart illustrating an embodiment of a polishing process for the substrate;

FIG. 16 is a diagram showing an example of parameters of polishing conditions in the low polishing-rate process and the high polishing-rate process;

FIG. 17 is a side view showing another embodiment of the substrate polishing apparatus;

FIG. 18 is a plan view of a conventional substrate polishing apparatus; and

FIG. 19 is a side view of the conventional substrate polishing apparatus shown in FIG. 18.

### DESCRIPTION OF EMBODIMENTS

Hereinafter, embodiments of the present invention will be described with reference to the drawings.

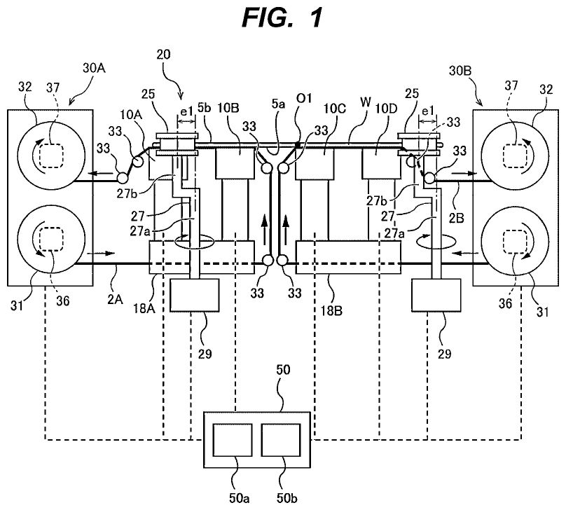

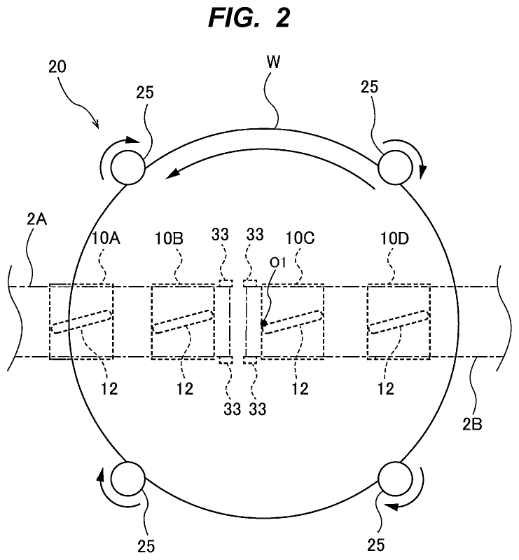

FIG. 1 is a side view showing an embodiment of a substrate polishing apparatus, and FIG. 2 is a plan view of the substrate polishing apparatus shown in FIG. 1. The substrate polishing apparatus shown in FIGS. 1 and 2 includes a substrate holder 20 configured to hold and rotate a substrate W, a plurality of polishing heads 10A to 10D configured to bring polishing tapes 2A and 2B into contact with a first surface 5a of the substrate W held by the substrate holder 20 to polish the first surface 5a of the substrate W, a polishing-tape feeding mechanism 30A configured to feed the polishing tape 2A in a longitudinal direction thereof, and a polishing-tape feeding mechanism 30B configured to feed the polishing tape 2B in a longitudinal direction thereof.

In this embodiment, the first surface 5a of the substrate W is a back surface of the substrate W on which no device is formed or device is not to be formed, i.e., a non-device surface. A second surface 5b of the substrate W, which is opposite the first surface 5a, is a surface on which devices are formed or devices are to be formed, i.e., a device surface. In this embodiment, the substrate W is horizontally supported by the substrate holder 20 with the first surface 5a, which is a surface to be polished, facing downward.

The substrate holder 20 includes a plurality of rollers 25 which can contact a periphery of the substrate W, a plurality of motors 29 configured to rotate the plurality of rollers 25, and a plurality of eccentric shafts 27 coupling the plurality of rollers 25 to the plurality of motors 29. In this embodiment, four rollers are provided, while five or more rollers may be provided.

Each eccentric shaft 27 has a first shaft portion 27a and a second shaft portion 27b extending in parallel. The second shaft portion 27b is decentered by a distance e1 from the first shaft portion 27a. The rollers 25 are secured to ends of the second shaft portions 27b, respectively. Axes of the rollers 25 coincide with axes of the second shaft portions 27b, respectively. The motors 29 are coupled to ends of the first shaft portions 27a, respectively.

When the motors 29 are in motion, the eccentric shafts 27 are rotated about their first shaft portions 27a. When the eccentric shafts 27 are rotated, each of the rollers 25 makes a circular motion with a radius e1 around the axis of the first shaft portion 27a. When each roller 25 makes one rotation around the axis of the first shaft portion 27a, each roller 25 makes one rotation about the axis of the roller 25. In this specification, the circular motion is defined as a movement of an object in a circular orbit.

The substrate holder 20 rotates the substrate W held by the rollers 25 about its own axis (the center) O1 while causing the substrate W to make a circular motion with the radius e1 by such movement of the rollers 25. Therefore, the substrate W and the polishing heads 10A to 10D make a circular motion relative to each other.

The polishing heads 10A and 10B are supported by a supporting member 18A, and the polishing heads 10C and 10D are supported by a supporting member 18B. The polishing heads 10A to 10D are disposed at a lower side of the substrate W held by the substrate holder 20. These polishing heads 10A to 10D are aligned in a diameter direction of the substrate W. In this embodiment, four polishing heads 10A to 10D are provided, while the number of polishing heads is not limited to this embodiment. In one embodiment, a single polishing head may be provided.

Since the polishing-tape feeding mechanisms 30A and 30B have the same configuration, the polishing-tape feeding mechanism 30A will be described below. The polishing-tape feeding mechanism 30A includes a tape feeding reel 31 to which one end of the polishing tape 2A is coupled, a tape take-up reel 32 to which the other end of the polishing tape 2A is coupled, and a plurality of guide rollers 33 configured to guide an advancing direction of the polishing tape 2A. The tape feeding reel 31 and the tape take-up reel 32 are coupled to reel motors 36 and 37, respectively.

The polishing tape 2A is advanced from the tape feeding reel 31 to the tape take-up reel 32 via the polishing heads 10A and 10B by rotating the tape take-up reel 32 in a direction indicated by an arrow in FIG. 1. The polishing tape 2A is fed above the polishing heads 10A and 10B such that a polishing surface of the polishing tape 2A faces the first surface 5a of the substrate W. The reel motor 36 can apply tension to the polishing tape 2A by applying a predetermined torque to the tape feeding reel 31. The reel motor 37 is controlled so as to advance the polishing tape 2A at a constant speed. An advancing speed of the polishing tape 2A can be changed by changing a rotation speed of the tape take-up reel 32.

In one embodiment, the substrate polishing apparatus may include a tape advancing device configured to feed the polishing tape 2A in the longitudinal direction thereof in addition to the tape feeding reel 31, the tape take-up reel 32, and the reel motors 36 and 37. In another embodiment, positions of the tape feeding reel 31 and the tape take-up reel 32 may be switched.

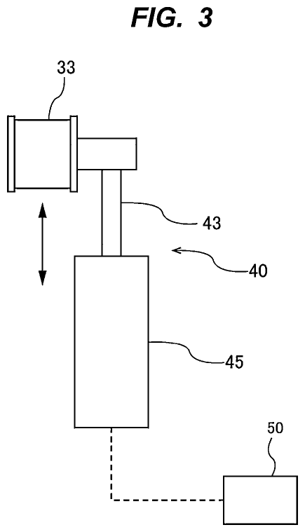

The substrate polishing apparatus further includes a guide-roller position adjusting mechanism 40 configured to vertically move the guide roller 33. FIG. 3 is a schematic diagram showing an embodiment of the guide-roller position adjusting mechanism 40. The guide-roller position adjusting mechanism 40 has an actuator 45 and a movable shaft 43. The movable shaft 43 extends in a vertical direction. One end of the movable shaft 43 is coupled to the guide roller 33, and the other end of the movable shaft 43 is coupled to the actuator 45. The actuator 45 is configured to raise and lower the movable shaft 43 to vertically move the guide roller 33 in a direction indicated by an arrow in FIG. 3. Examples of the actuator 45 include a piston cylinder device including a piston for vertically moving the movable shaft 43, a combination of a servomotor and gears, etc.

The guide-roller position adjusting mechanism 40 is coupled to each of the plurality of guide rollers 33. In one embodiment, the guide-roller position adjusting mechanism(s) 40 may be coupled only to the guide rollers 33 adjacent to the polishing heads 10A to 10D. The specific configuration of the guide-roller position adjusting mechanism 40 is not limited to the embodiment shown in FIG. 3 as long as the guide rollers 33 can be vertically moved. In another embodiment, the guide-roller position adjusting mechanism 40 may not have the actuator 45, and may include a guide member configured to support the guide roller 33, and a fixing member configured to fix a relative position of the guide roller 33 with respect to the guide member. In still another embodiment, the substrate polishing apparatus may not include the guide-roller position adjusting mechanism 40.

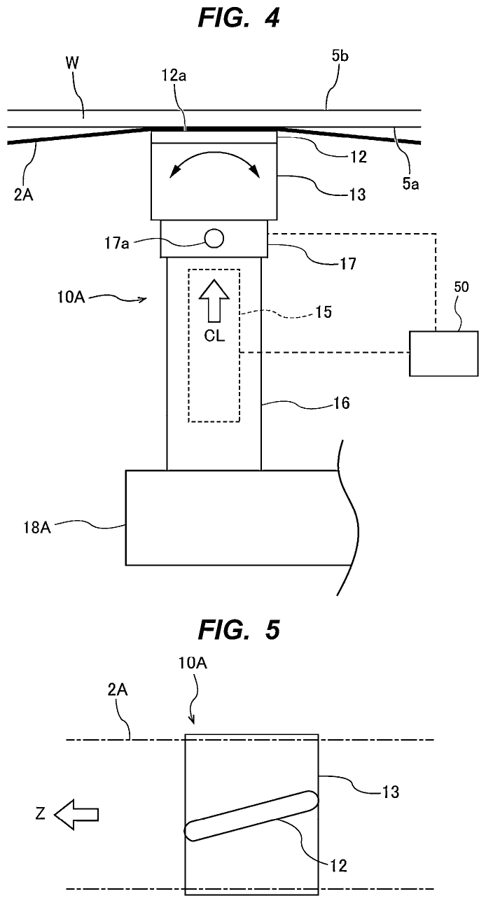

FIG. 4 is a side view showing an embodiment of the polishing head 10A, and FIG. 5 is a plan view of the polishing head TOA shown in FIG. 4. Since the polishing heads TOA to 10D basically have the same configuration, the polishing head TOA will be described below. The polishing head 10A is disposed under the substrate W and the polishing tape 2A, and is arranged so as to press the polishing tape 2A against the back surface of the substrate W from a back side of the polishing tape 2A.

The polishing head 10A includes a pressing member 12 configured to press the polishing tape 2A against the substrate W, a pressing-member holder 13 configured to hold the pressing member 12, a polishing-head actuator 15 configured to apply a pressing force to the pressing member 12, a polishing-head housing 16 coupled to the supporting member 18A, and a tilting mechanism 17 configured to tilt the pressing-member holder 13.

The pressing member 12 is a blade having a shape extending in a straight line, and has a pressing surface 12a for pressing the polishing tape 2A against the substrate W. The pressing member 12 is fixed to the pressing-member holder 13. The pressing member 12 is arranged obliquely with respect to the advancing direction of the polishing tape 2A indicated by an arrow Z in FIG. 5. The pressing member 12 is made of an elastic material. Examples of the material constituting the pressing member 12 include rubber, such as fluororubber, silicone rubber, and ethylene propylene diene rubber. A cross section of the pressing member 12 has a circular shape.

However, the configuration of the pressing member 12 is not limited to this embodiment, and the pressing member 12 may have another shape or may be made of another material. In one embodiment, the pressing member 12 may be arranged perpendicular to the advancing direction of the polishing tape 2A. In another embodiment, the pressing member 12 may have two blades, or may be a blade having a curved shape.

The polishing-head actuator 15 is disposed in the polishing-head housing 16, and is coupled to the pressing-member holder 13 by a not-shown coupling member. The polishing-head actuator 15 is configured to move the pressing-member holder 13 and the pressing member 12 in a pressing direction indicated by an arrow CL in FIG. 4 to generate a tape pressing force which is a force to press the polishing tape 2A against the substrate W.

The tilting mechanism 17 is fixed to the pressing-member holder 13. The tilting mechanism 17 has a support shaft 17a, and can rotate the pressing-member holder 13 about an axis of the support shaft 17a at a predetermined angle by a motor (not shown). Therefore, the tilting mechanism 17 is configured to tilt the pressing-member holder 13 and the pressing member 12 with respect to the pressing direction indicated by the arrow CL. Furthermore, the tilting mechanism 17 is configured to maintain the angle of the pressing-member holder 13 and the pressing member 12 that have been tilted. An example of the motor is a servomotor or a stepping motor. The specific configuration of the tilting mechanism 17 is not limited to the embodiment shown in FIG. 4 as long as the pressing member 12 can be tilted with respect to the pressing direction indicated by the arrow CL. In another embodiment, the tilting mechanism 17 may not have the motor that tilts the pressing member 12, and may include a supporting member configured to rotatably support the pressing member 12, and a fixing member configured to fix a relative angle of the pressing member 12 with respect to the supporting member. In still another embodiment, the substrate polishing apparatus may not include the tilting mechanism 17.

The substrate polishing apparatus is electrically coupled to an operation controller 50 configured to control operations of each component of the substrate polishing apparatus. The motors 29 of the substrate holder 20, the polishing-head actuator 15 and the tilting mechanism 17 of each of the polishing heads 10A to 10D, the polishing-tape feeding mechanisms 30A and 30B, and the actuators 45 of the guide-roller position adjusting mechanisms 40 are electrically coupled to the operation controller 50. Operations of the substrate holder 20, the polishing heads 10A to 10D, the polishing-tape feeding mechanisms 30A and 30B, and the guide-roller position adjusting mechanisms 40 are controlled by the operation controller 50.

The operation controller 50 includes at least one computer. The operation controller 50 includes a memory 50a storing programs therein, and an arithmetic device 50b configured to perform arithmetic operations according to the programs. The memory 50a includes a main memory (e.g., a random access memory) to which the arithmetic device 50b is accessible, and an auxiliary memory (e.g., a hard disk drive or a solid state drive) configured to store the programs. The arithmetic device 50b includes a CPU (central processing unit) or a GPU (graphics processing unit) configured to perform the arithmetic operations according to instructions contained in the programs stored in the memory 50a. However, the specific configuration of the operation controller 50 is not limited to these examples.

Polishing of the substrate W is performed as follows. The substrate holder 20 holds the periphery of the substrate W with the plurality of rollers 25, and rotates the plurality of eccentric shafts 27 to cause the plurality of rollers 25 to make the circular motions. The substrate holder 20 causes the substrate W and the polishing heads TOA to 10D to make a circular motion relative to each other, while rotating the substrate W about its own axis O1. The pressing members 12 of the polishing heads 10A to 10D press the polishing tapes 2A and 2B against the first surface 5a of the substrate W, while the polishing-tape feeding mechanisms 30A and 30B feed the polishing tapes 2A and 2B to the polishing heads 10A to 10D, so that the first surface 5a of the substrate W is polished with the polishing tapes 2A and 2B.

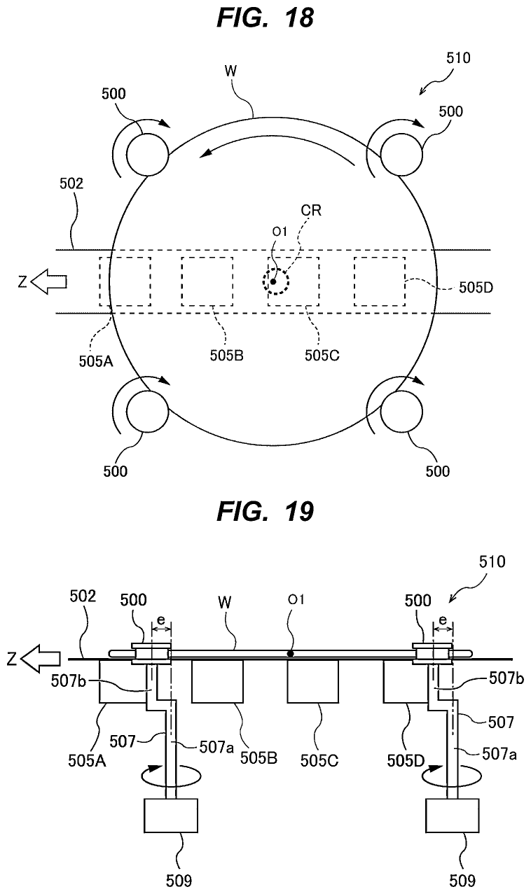

As described with reference to FIGS. 18 and 19, a central region including the center O1 of the substrate W may be excessively polished compared to a region other than the central region. In order to prevent the central region from being excessively polished, in this embodiment, a polishing process performed by the polishing head 10C, which polishes the region including the center O1 of the substrate W, of the plurality of polishing heads 10A to 10D includes at least two polishing processes performed under different polishing conditions. The polishing head 10C polishes the central region including the center O1 of the substrate W in the first surface 5a and polishes an outer region adjacent to the central region. The at least two polishing processes performed by the polishing head 10C include a low polishing-rate process performed under polishing conditions such that a polishing rate in the central region is lower than a polishing rate in the outer region, and a high polishing-rate process performed under polishing conditions such that the polishing rate in the central region is higher than the polishing rate in the outer region.

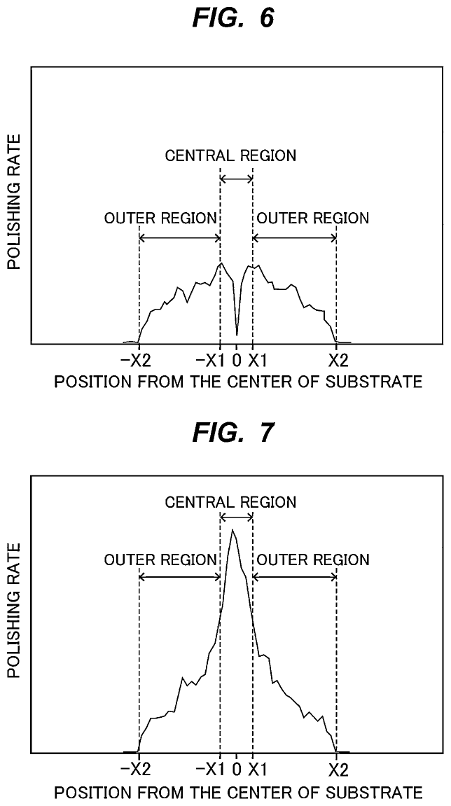

FIG. 6 is a graph showing a relationship between a position from the center O1 of the substrate W and a polishing rate in the low polishing-rate process, and FIG. 7 is a graph showing a relationship between a position from the center O1 of the substrate W and a polishing rate in the high polishing-rate process. The graphs in FIG. 6 and FIG. 7 have been obtained when the polishing head 10C presses the polishing tape 2B to polish the first surface 5a of the substrate W. The position from the center O1 of the substrate W represents a position from the center O1 of the substrate W on a straight line that passes through the center O1 of the substrate W and is along an advancing direction of the polishing tape 2B. In other words, the position from the center O1 of the substrate W represents a position in the radial direction of the substrate W. A negative value of the position from the center O1 of the substrate W indicates a position located upstream of the center O1 of the substrate W in the advancing direction of the polishing tape 2B, and a positive value of the position from the center O1 of the substrate W indicates a position located downstream of the center O1 of the substrate W in the advancing direction of the polishing tape 2B.

In this embodiment, the central region is a region whose distance from the center O1 of the substrate W is from 0 to X1, and the outer region is a region whose distance from the center O1 of the substrate W is from X1 to X2. The outer region is located outwardly of the central region in the radial direction of the substrate W. As shown in FIG. 6, in the low polishing-rate process, the polishing rate in the central region is lower than the polishing rate of the outer region. As shown in FIG. 7, in the high polishing-rate process, the polishing rate in the central region is higher than the polishing rate of the outer region.

These polishing rates can be adjusted by parameter(s) of the polishing conditions. The parameter(s) of the polishing conditions include at least one of a tape pressing force generated by the polishing head 10C, a tape tension of the polishing tape 2B, a position of the guide roller 33 arranged adjacent to the polishing head 10C, an angle of the pressing member 12 of the polishing head 10C inclined downwardly toward the center O1 of the substrate W, an outer diameter of the guide roller 33 arranged adjacent to the polishing head 10C, a length of the pressing member 12 of the polishing head 10C, and a hardness of the pressing member 12 of the polishing head 10C.

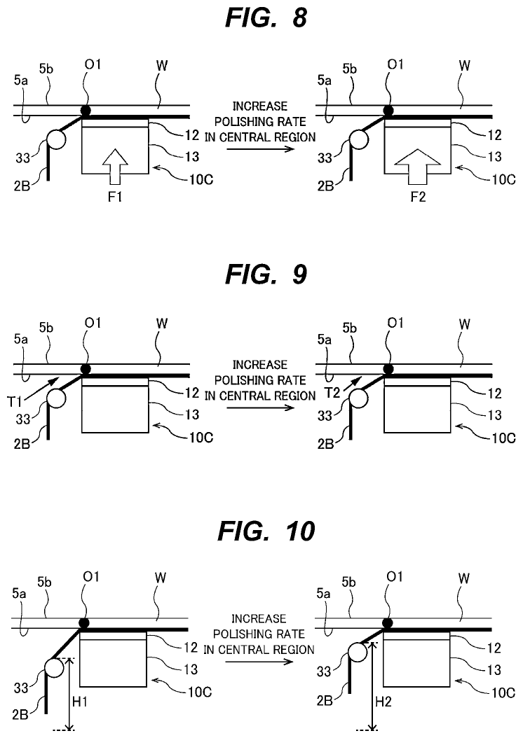

FIG. 8 is a diagram illustrating a variation of polishing rate in the central region with a difference in tape pressing force. The tape pressing force generated by the polishing head 10C can be adjusted by the polishing-head actuator 15 shown in FIG. 4. When a tape pressing force F2 is larger than a tape pressing force F1, the polishing rate in the central region when the substrate W is polished with the tape pressing force F2 is higher than the polishing rate in the central region when the substrate W is polished with the tape pressing force F1. Therefore, the tape pressing force in the polishing conditions of the high polishing-rate process is larger than the tape pressing force in the polishing conditions of the low polishing-rate process.

FIG. 9 is a diagram illustrating a variation of polishing rate in the central region with a difference in tape tension. The tape tension can be adjusted by the torque applied to the tape feeding reel 31 by the reel motor 36 shown in FIG. 1. When a tape tension T2 is smaller than a tape tension T1, the polishing rate in the central region when the substrate W is polished with the tape tension T2 is higher than the polishing rate in the central region when the substrate W is polished with the tape tension T1. Therefore, the tape tension in the polishing conditions of the high polishing-rate process is smaller than the tape tension in the polishing conditions of the low polishing-rate process.

FIG. 10 is a diagram illustrating a variation of polishing rate in the central region with a difference in position of the guide roller 33 arranged adjacent to the polishing head 10C. The position of the guide roller 33 arranged adjacent to the polishing head 10C can be adjusted by the guide-roller position adjusting mechanism 40 shown in FIG. 3. When a height H2 is higher than a height H1, the polishing rate in the central region when the substrate W is polished with the position of the guide roller 33 at the height H2 is higher than the polishing rate in the central region when the substrate W is polished with the position of the guide roller 33 at the height H1. Therefore, the position of the guide roller 33 arranged adjacent to the polishing head 10C in the polishing conditions of the high polishing-rate process is higher than the position of the guide roller 33 in the polishing conditions of the low polishing-rate process.

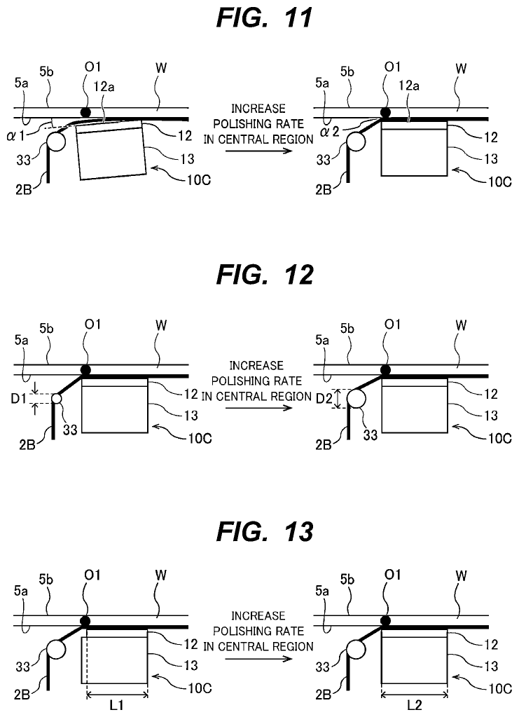

FIG. 11 is a diagram illustrating a variation of polishing rate in the central region with a difference in angle of the pressing member 12 of the polishing head 10C. The angle of the pressing member 12 of the polishing head 10C is an angle of the pressing surface 12a of the pressing member 12 with respect to the first surface 5a of the substrate W. The angle of the pressing member 12 of the polishing head 10C can be adjusted by the tilting mechanism 17 shown in FIG. 4. When an angle α2 (in FIG. 11, the angle α2 is 0 degrees) of the pressing member 12 of the polishing head 10C inclined downwardly toward the center O1 of the substrate W is smaller than an angle α1, the polishing rate in the central region when the substrate W is polished with the angle α2 of the pressing member 12 is higher than the polishing rate in the central region when the substrate W is polished with the angle α1 of the pressing member 12. Therefore, the angle of the pressing member 12 of the polishing head 10C inclined downwardly toward the center O1 of the substrate W in the polishing conditions of the high polishing-rate process is smaller than the angle of the pressing member 12 of the polishing head 10C inclined downwardly toward the center O1 of the substrate W in the polishing conditions of the low polishing-rate process.

FIG. 12 is a diagram illustrating a variation of polishing rate in the central region with a difference in outer diameter of the guide roller 33 arranged adjacent to the polishing head 10C. When the axes of the guide rollers 33 are located at the same position, and an outer diameter D2 of the guide roller 33 is larger than an outer diameter D1 of the guide roller 33, the polishing rate in the central region when the substrate W is polished with the outer diameter D2 of the guide roller 33 is higher than the polishing rate in the central region when the substrate W is polished with the outer diameter D1 of the guide roller 33. Therefore, the outer diameter of the guide roller 33 arranged adjacent to the polishing head 10C in the polishing conditions of the high polishing-rate process is larger than the outer diameter of the guide roller 33 in the polishing conditions of the low polishing-rate process.

FIG. 13 is a diagram illustrating a variation of polishing rate in the central region with a difference in length of the pressing member 12 of the polishing head 10C. When a length L2 is longer than a length L1 in a direction toward the center O1 of the substrate W, the polishing rate in the central region when the pressing member 12 of the polishing head 10C having the length L2 polishes the substrate W is higher than the polishing rate in the central region when the pressing member 12 of the polishing head 10C having the length L1 polishes the substrate W. Therefore, the length of the pressing member 12 of the polishing head 10C in the polishing conditions of the high polishing-rate process is longer than the length of the pressing member 12 of the polishing head 10C in the polishing conditions of the low polishing-rate process in the direction toward the center O1 of the substrate W. The length of the pressing member 12 of the polishing head 10C is a length along the longitudinal direction of the polishing tape 2B.

Furthermore, the polishing rate in the central region also varies depending on a difference in hardness of the pressing member 12 of the polishing head 10C. The hardness of the pressing member 12 can be adjusted by the material constituting the pressing member 12. The polishing rate in the central region when the hardness of the pressing member 12 of the polishing head 10C is low is higher than the polishing rate in the central region when the hardness of the pressing member 12 of the polishing head 10C is high. Therefore, the hardness of the pressing member 12 of the polishing head 10C in the polishing conditions of the high polishing-rate process is lower than the hardness of the pressing member 12 of the polishing head 10C in the polishing conditions of the low polishing-rate process.

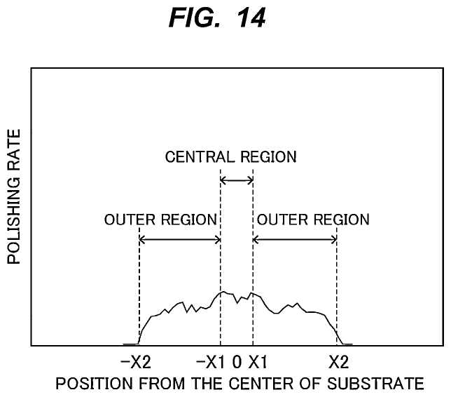

FIG. 14 is a graph showing a relationship between the position from the center O1 of the substrate W and a polishing rate in the polishing process including the low polishing-rate process and the high polishing-rate process. As shown in FIG. 14, the process of polishing the central region and the outer region performed by the polishing head 10C includes at least two polishing processes including the low polishing-rate process and the high polishing-rate process such that the polishing rate in the central region and the polishing rate in the outer region are uniform. The polishing conditions in each polishing process performed by the polishing head 10C are determined based on data of past polishing results for substrate(s). More specifically, the above-described parameter(s) of the polishing conditions in the low polishing-rate process and the high polishing-rate process is determined based on data of past polishing results for substrate(s) with change in the parameters of the polishing conditions.

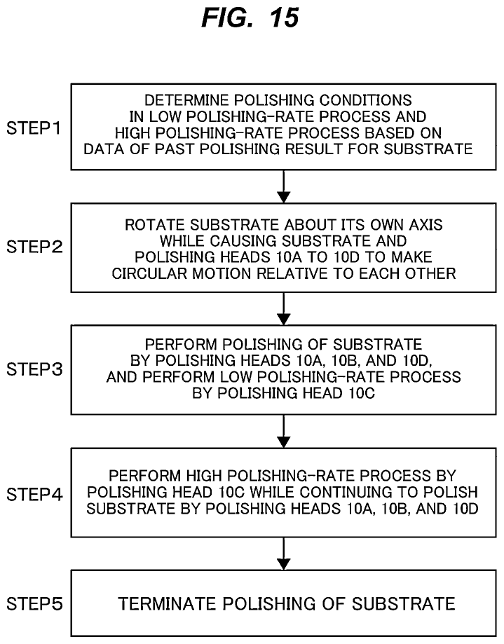

FIG. 15 is a flow-chart illustrating an embodiment of the polishing process for the substrate W.

In step 1, polishing conditions in the low polishing-rate process and the high polishing-rate process performed by the polishing head 10C are determined based on data of past polishing result(s) for substrate(s).

In step 2, the substrate holder 20 rotates the substrate W about its own axis O1, while causing the substrate W and the polishing heads 10A to 10D to make a circular motion relative to each other.

In step 3, the polishing heads 10A and 10B press the polishing tape 2A against the first surface 5a of the substrate W, so that the substrate W is polished. Further, the polishing heads 10C and 10D press the polishing tape 2B against the first surface 5a of the substrate W, so that the substrate W is polished. The low polishing-rate process is performed by the polishing head 10C under the determined polishing conditions.

In step 4, the high polishing-rate process is performed by the polishing head 10C under the determined polishing conditions while polishing of the substrate W is continued by the polishing heads 10A, 10B, and 10D. In other words, polishing of the substrate W performed by the polishing head 10C is changed from the low polishing-rate process to the high polishing-rate process with the change in the polishing conditions. Therefore, the polishing rates of the central region and the outer region of the substrate W become uniform, and as a result, the entire first surface 5a of the substrate W can be polished at a uniform polishing rate.

In step 5, polishing of the substrate W performed by the polishing heads 10A to 10D is terminated.

In this embodiment, the high polishing-rate process is performed after the low polishing-rate process by the polishing head 10C, but the polishing process performed by the polishing head 10C is not limited to this embodiment. In one embodiment, the low polishing-rate process may be performed after the high polishing-rate process by the polishing head 10C. In another embodiment, the polishing process performed by the polishing head 10C may include three or more polishing processes. For example, one high polishing-rate process may be performed by the polishing head 10C after two low polishing-rate processes are performed by the polishing head 10C under different polishing conditions.

In the step 4 in FIG. 15, when the polishing of the substrate W performed by the polishing head 10C is changed from the low polishing-rate process to the high polishing-rate process, it is necessary to change parameter(s) of the polishing conditions that can be changed during polishing of the substrate W. Therefore, the parameter(s) of the polishing conditions to be changed during polishing of the substrate W includes at least one of the tape pressing force generated by the polishing head 10C, the tape tension of the polishing tape 2B, the position of the guide roller 33 arranged adjacent to the polishing head 10C, and the angle of the pressing member 12 of the polishing head 10C inclined downwardly toward the center O1 of the substrate W of the above-described parameters of the polishing conditions.

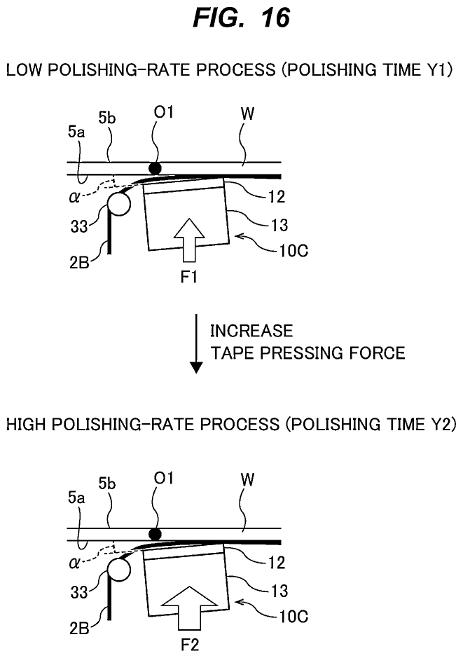

FIG. 16 is a diagram showing an example of parameters of the polishing conditions in the low polishing-rate process and the high polishing-rate process. In the polishing conditions in the low polishing-rate process, the angle of the pressing member 12 of the polishing head 10C inclined downwardly toward the center O1 of the substrate W is an angle α, and the tape pressing force generated by the polishing head 10C is a tape pressing force F1. In the polishing conditions in the high polishing-rate process, the angle of the pressing member 12 of the polishing head 10C inclined downwardly toward the center O1 of the substrate W is the angle α, and the tape pressing force generated by the polishing head 10C is a tape pressing force F2 which is larger than the tape pressing force F1. Parameters of the polishing conditions other than the tape pressing force in the high polishing-rate process are the same as those in the low polishing-rate process. In this example, the low polishing-rate process is performed for a polishing time YT, and the high polishing-rate process is then performed for a polishing time Y2.

In the example in FIG. 16, the low polishing-rate process is performed at the angle α of the pressing member 12 inclined downwardly toward the center O1 of the substrate W. Further, the high polishing-rate process is performed by changing the tape pressing force generated by the polishing head 10C to tape pressing force F2, which is larger than the tape pressing force F1. As a result, the polishing rates in the central region and the outer region of the substrate W become uniform, so that the entire first surface 5a of the substrate W can be polished at a uniform polishing rate.

The polishing time Y1 of the low polishing-rate process and the polishing time Y2 of the high polishing-rate process are determined to be appropriate times based on, for example, a polishing result of a test substrate. Alternatively, during the high polishing-rate process, a polishing profile of the substrate W may be measured at predetermined time intervals, and the high polishing-rate process may be terminated when an appropriate polishing profile is reached.

The parameters of the polishing conditions in the low polishing-rate process and the high polishing-rate process shown in FIG. 16 are one example. The parameters of the polishing conditions in the low polishing-rate process and the high polishing-rate process may be another parameter, which may be, for example, the tape tension of the polishing tape 2B or the position of the guide roller 33 arranged adjacent to the polishing head 10C, or may be a combination of a plurality of parameters including other parameters.

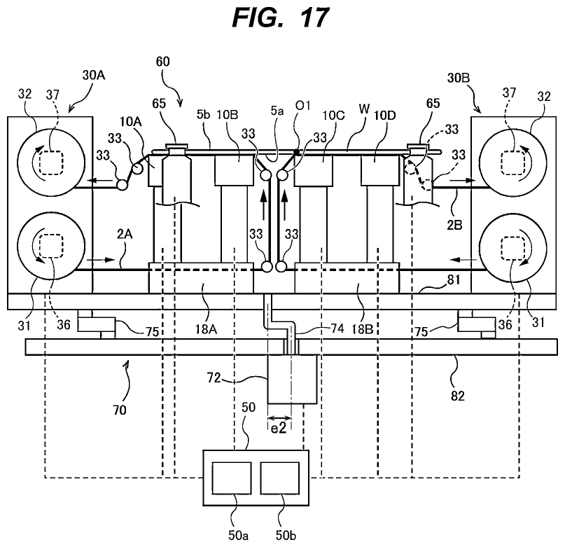

FIG. 17 is a side view showing another embodiment of the substrate polishing apparatus. Configurations of the substrate polishing apparatus of this embodiment, which will not be particularly described, are the same as the configurations of the substrate polishing apparatus described with reference to FIGS. 1 to 5, and duplicated descriptions will be omitted. The substrate polishing apparatus of this embodiment differs from the substrate polishing apparatus of the embodiment described with reference to FIGS. 1 to 5 in a configuration of a substrate holder 60. The substrate polishing apparatus of this embodiment further includes a table circularly moving mechanism 70 configured to cause the polishing heads 10A to 10D and the polishing-tape feeding mechanisms 30A and 30B to make a circular motion.

The substrate holder 60 includes a plurality of rollers 65 which can contact the periphery of the substrate W, and a roller rotating device (not shown) configured to rotate the plurality of rollers 65 at the same speed. The substrate W is horizontally held by the substrate holder 60 with the first surface 5a facing downward. In this embodiment, four rollers 65 are provided, while five or more rollers may be provided.

The plurality of polishing heads 10A to 10D are disposed at the lower side of the substrate W held by the substrate holder 60. The table circularly moving mechanism 70 is disposed below the polishing heads 10A to 10D and the polishing-tape feeding mechanisms 30A and 30B. The supporting member 18A configured to support the polishing heads 10A and 10B, the supporting member 18B configured to support the polishing heads 10C and 10D, and the polishing-tape feeding mechanisms 30A and 30B are coupled to the table circularly moving mechanism 70.

The table circularly moving mechanism 70 includes a table motor 72, a crankshaft 74 fixed to the table motor 72, a table 81, a base 82, and a plurality of eccentric joints 75. The table motor 72 is disposed at a lower side of the base 82, and is fixed to a lower surface of the base 82. The crankshaft 74 extends upwardly through the base 82. The table 81 is coupled to the plurality of eccentric joints 75 and the crankshaft 74. The base 82 is coupled to the plurality of eccentric joints 75. The table 81 is coupled to the base 82 via the plurality of eccentric joints 75 and the crankshaft 74. Although only two eccentric joints 75 are shown in FIG. 17, the table circularly moving mechanism 70 includes at least two eccentric joints 75.

A distal end of the crankshaft 74 is decentered by a distance e2 from an axis of the table motor 72. Accordingly, when the table motor 72 is in motion, the table 81 makes a circular motion with a radius e2. Since the table 81 is supported by the plurality of eccentric joints 75, the table 81 itself does not rotate when the table 81 is making the circular motion. The eccentricity of each of the plurality of eccentric joints 75 is equal to the eccentricity of the table 81. The polishing heads 10A to 10D and the polishing-tape feeding mechanisms 30A and 30B are fixed to the table 81.

When the table circularly moving mechanism 70 is in motion, the polishing heads 10A to 10D and the polishing-tape feeding mechanisms 30A and 30B make the circular motion together. Therefore, the substrate W held by the substrate holder 60 and the polishing heads 10A to 10D make the circular motion relative to each other.

The roller rotating device of the substrate holder 60 and the table motor 72 of the table circularly moving mechanism 70 are electrically coupled to the operation controller 50. Operations of the substrate holder 60 and the table circularly moving mechanism 70 are controlled by the operation controller 50.

Polishing of the substrate W is performed as follows. The substrate holder 60 holds the periphery of the substrate W with the plurality of rollers 65, and rotates the substrate W. The table circularly moving mechanism 70 causes the polishing heads 10A to 10D and the polishing-tape feeding mechanisms 30A and 30B to make a circular motion together to cause the substrate W and the polishing heads 10A to 10D to make a circular motion relative to each other. The pressing members 12 of the polishing heads 10A to 10D press the polishing tapes 2A and 2B against the first surface 5a of the substrate W, while the polishing-tape feeding mechanisms 30A and 30B feed the polishing tapes 2A and 2B to the polishing heads 10A to 10D, so that the first surface 5a of the substrate W is polished.

As with the embodiments described with reference to FIGS. 6 to 16, a polishing process performed by the polishing head 10C, which polishes the region including the center O1 of the substrate W, of the plurality of polishing heads 10A to 10D of the substrate polishing apparatus shown in FIG. 17 includes at least two polishing processes performed under different polishing conditions. More specifically, the at least two polishing processes performed by the polishing head 10C include at least two polishing processes including a low polishing-rate process and a high polishing-rate process which are such that the polishing rate in the central region and the polishing rate in the outer region are uniform. The polishing process of this embodiment is the same as the polishing process described with reference to FIGS. 6 to 16, and duplicated description will be omitted.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

### INDUSTRIAL APPLICABILITY

The present invention is applicable to a substrate polishing method of polishing a substrate, such as a wafer.

### REFERENCE SIGNS LIST

2A, 2B polishing tape
5a first surface
5b second surface
10A, 10B, 10C, 10D polishing head
12 pressing member
13 pressing-member holder
15 polishing-head actuator
16 polishing-head housing
17 tilting mechanism
17a support shaft
18A, 18B supporting member
20 substrate holder
25 roller
27 eccentric shaft
27a first shaft portion
27b second shaft portion
29 motor
30A, 30B polishing-tape feeding mechanism
31 tape feeding reel
32 tape take-up reel
33 guide roller
36, 37 reel motor
40 guide-roller position adjusting mechanism
43 movable shaft
45 actuator
50 operation controller
50a memory
50b arithmetic device
60 substrate holder
65 roller
70 table circularly moving mechanism
72 table motor
74 crankshaft
75 eccentric joint
81 table
82 base

1. A substrate polishing method of polishing a surface of a substrate, comprising:
rotating the substrate about its own axis, while causing the substrate and a polishing head to make a circular motion relative to each other; and
pressing a polishing tape against the surface of the substrate by the polishing head while feeding the polishing tape in a longitudinal direction thereof to thereby polish a central region including a center of the substrate and an outer region adjacent to the central region,
wherein a process of polishing the central region and the outer region includes at least two polishing processes performed under different polishing conditions, and
the at least two polishing processes include:
a low polishing-rate process performed under a polishing condition such that a polishing rate in the central region is lower than a polishing rate in the outer region; and
a high polishing-rate process performed under a polishing condition such that a polishing rate in the central region is higher than a polishing rate in the outer region.

2. The substrate polishing method according to claim 1, wherein a parameter of the polishing condition includes at least one of a tape pressing force generated by the polishing head, a tape tension of the polishing tape, a position of a guide roller configured to guide the polishing tape, the guide roller being arranged adjacent to the polishing head, an outer diameter of the guide roller, a length of a pressing member of the polishing head, the pressing member being configured to press the polishing tape against the substrate, an angle of the pressing member inclined downwardly toward the center of the substrate, and a hardness of the pressing member.

3. The substrate polishing method according to claim 2, wherein the tape pressing force in the polishing condition of the high polishing-rate process is larger than the tape pressing force in the polishing condition of the low polishing-rate process.

4. The substrate polishing method according to claim 2, wherein the tape tension of the polishing tape in the polishing condition of the high polishing-rate process is smaller than the tape tension of the polishing tape in the polishing condition of the low polishing-rate process.

5. The substrate polishing method according to claim 2, wherein the position of the guide roller in the polishing condition of the high polishing-rate process is higher than the position of the guide roller in the polishing condition of the low polishing-rate process.

6. The substrate polishing method according to claim 2, wherein the angle of the pressing member inclined downwardly toward the center of the substrate in the polishing condition of the high polishing-rate process is smaller than the angle of the pressing member inclined downwardly toward the center of the substrate in the polishing condition of the low polishing-rate process.
